(19) United States
(12) Patent Application Publication
(10) Pub. No.: US 2025/0216478 A1
(43) Pub. Date: Jul. 3, 2025

(54) COOLING PLATE FOR BATTERY, BATTERY ASSEMBLY, AND INSPECTION METHOD THEREFOR

(71) Applicant: TOYOTA JIDOSHA KABUSHIKI KAISHA, Toyota-shi (JP)

(72) Inventor: Shinya ISHIKAWA, Anjo-shi (JP)

(73) Assignee: TOYOTA JIDOSHA KABUSHIKI KAISHA, Toyoata-shi (JP)

(21) Appl. No.: 18/899,502

(22) Filed: Sep. 27, 2024

(30) Foreign Application Priority Data
Dec. 28, 2023 (JP) 2023-222760

(51) Int. Cl. G01R 31/52; G01R 31/54; H01M 10/42; H01M 10/613; H01M 10/6554

(52) U.S. Cl. CPC G01R 31/52; G01R 31/54; H01M 10/42; H01M 10/613; H01M 10/6554; H01M 2220/20

(57) ABSTRACT

A cooling plate for battery of the present disclosure includes a flat surface portion, and a pair of side surface portions facing each other. In the cooling plate for battery, a cutout or through-hole is formed in at least one of the side surface portions. A battery assembly of the present disclosure includes the cooling plate for battery, and a battery disposed on the flat surface portion of the cooling plate for battery. The battery in the battery assembly includes an electrode stack, a current collector terminal, and a laminating film. The laminating film includes a fusion resin layer, a metal layer, and a protection resin layer, and an extending portion. The extending portion is bent toward the electrode stack, and the cooling plate for battery is disposed such that at least one of the side surface portions of the cooling plate for battery faces the bent extending portion.

### CROSS-REFERENCE TO RELATED APPLICATION

This application claims priority to Japanese Patent Application No. 2023-222760 filed on Dec. 28, 2023, incorporated herein by reference in its entirety.

### BACKGROUND

### 1. Technical Field

The present disclosure relates to a cooling plate for battery, a battery assembly, and an inspection method therefor.

### 2. Description of Related Art

A battery including an electrode stack, a current collector terminal, and a laminating film is known. The current collector terminal is electrically connected to a current collector portion of the electrode stack, and the laminating film seals the electrode stack. Such a battery may generate heat in charging and discharging, and this heat generation may reduce the battery performance. Such a problem is particularly remarkable in a battery module formed of a plurality of batteries, and hence a method for promoting heat dissipation in the battery module has been developed.

WO 2015/019429 A1 discloses a battery module including a plurality of heat dissipation plates (cooling plates), a laminated type battery disposed between the heat dissipation plates, and a case that houses the laminated type battery and the heat dissipation plates.

In WO 2015/019429 A1, the heat dissipation plate includes a contact portion corresponding to both end portions being bent, and a flat surface portion. The heat dissipation plate is disposed in a form in which the contact portion is in close contact with a side surface of the case and the flat surface portion is in close contact with a wide surface of the laminated type battery. Thus, heat generated from the laminated type battery in the charging and discharging is conducted to the case side and each unit cell is thus cooled.

### SUMMARY

However, insulation is required to be ensured between metal materials configuring a battery assembly formed by assembling a battery and cooling plates (referred to as heat dissipation plates in WO 2015/019429 A1), specifically, between a metal layer of the laminating film and the current collector terminal and between the above-mentioned metal layer and the cooling plate. The disclosers and the like of the subject application have proposed performing an insulation inspection for evaluating presence or absence of a short-circuit between the metal materials configuring such a battery assembly. However, the disclosers and the like of the subject application have found that the cooling plate may become an obstacle of such an insulation inspection.

The present disclosure has an object to provide a cooling plate for battery that is less liable to become an obstacle of an insulation inspection, a battery assembly including such a cooling plate for battery, and an inspection method therefor.

The disclosers and the like of the subject application have found that the above-mentioned problems can be solved by the following means.

### Aspect 1

A cooling plate for battery including: a flat surface portion; and a pair of side surface portions facing each other, in which a cutout or through-hole is formed in at least one of the side surface portions.

### Aspect 2

The cooling plate for battery according to aspect 1, in which the cutout or through-hole may be provided in at least one end portion of the side surface portions.

### Aspect 3

A battery assembly including: the cooling plate for battery of aspect 1 or 2; and a battery disposed on the flat surface portion of the cooling plate for battery, in which:
the battery includes an electrode stack, a current collector terminal electrically connected to a current collector portion of the electrode stack, and a laminating film that seals the electrode stack;
the laminating film includes a fusion resin layer, a metal layer, and a protection resin layer, and also an extending portion extending at a peripheral edge of the electrode stack;
the extending portion is bent toward the electrode stack; and
the cooling plate for battery is disposed such that at least one of the side surface portions of the cooling plate for battery faces the bent extending portion.

### Aspect 4

An inspection method for the battery assembly of aspect 3, the inspection method including the following steps of:
(a) piercing the extending portion of the laminating film with a first inspection terminal through the cutout or through-hole of the cooling plate for battery of aspect 1 or 2 to bring the first inspection terminal into contact with the metal layer;
(b) bringing a second inspection terminal into contact with the current collector terminal, and evaluating continuity between the first inspection terminal and the second inspection terminal to evaluate presence or absence of a short-circuit between the metal layer and the current collector terminal; and
(c) bringing a third inspection terminal into contact with the cooling plate for battery, and evaluating continuity between the first inspection terminal and the third inspection terminal to evaluate presence or absence of a short-circuit between the metal layer and the cooling plate for battery.

### Aspect 5

The inspection method of aspect 4 may further include the following steps before the step (a):
piercing the extending portion of the laminating film with two first inspection terminals at positions different from each other to bring the two first inspection terminals into contact with the metal layer, and checking continuity between the two first inspection terminals;
bringing two second inspection terminals into contact with the current collector terminal at positions different from each other, and checking continuity between the two second inspection terminals; and
bringing two third inspection terminals into contact with the cooling plate for battery at positions different from each other, and checking continuity between the two third inspection terminals.

According to the present disclosure, it is possible to provide the cooling plate for battery that is less liable to become an obstacle of an insulation inspection, the battery assembly including such a cooling plate for battery, and the inspection method therefor.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic perspective view illustrating an example of a cooling plate for battery of the present disclosure;

FIG. 2 is a schematic perspective view illustrating an example of a battery assembly of the present disclosure;

FIG. 3A is a schematic side view illustrating an example of an inspection method for the battery assembly including the cooling plate for battery of the present disclosure;

FIG. 3B is a schematic side view illustrating an example of the inspection method for the battery assembly including the cooling plate for battery of the present disclosure;

FIG. 4 is a schematic plan view illustrating an example of the inspection method for the battery assembly including the cooling plate for battery of the present disclosure;

FIG. 5 is a schematic perspective view illustrating an example of a cooling plate for battery according to the related art;

FIG. 6 is a schematic side view illustrating an example of an inspection method for a battery assembly including the cooling plate for battery according to the related art; and

FIG. 7 is a schematic side view illustrating an example of the inspection method for the battery assembly including the cooling plate for battery according to the related art.

### DETAILED DESCRIPTION OF EMBODIMENTS

Hereinafter, with reference to the drawings, an embodiment of the present disclosure is described in detail. Note that the present disclosure is not limited to the following embodiment, and various modifications can be made thereto without departing from the gist of the disclosure. Further, dimensional relationships in the drawings do not reflect actual dimensional relationships.

### Cooling Plate for Battery

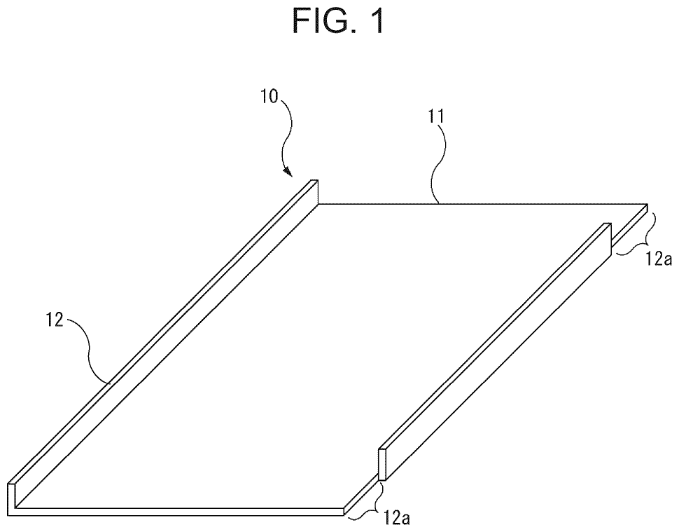

As exemplified in FIG. 1, a cooling plate 10 for battery of the present disclosure includes a flat surface portion 11, and a pair of side surface portions 12 facing each other. In the cooling plate 10 for battery of the present disclosure, at least one of the side surface portions 12 has a cutout or through-hole 12a.

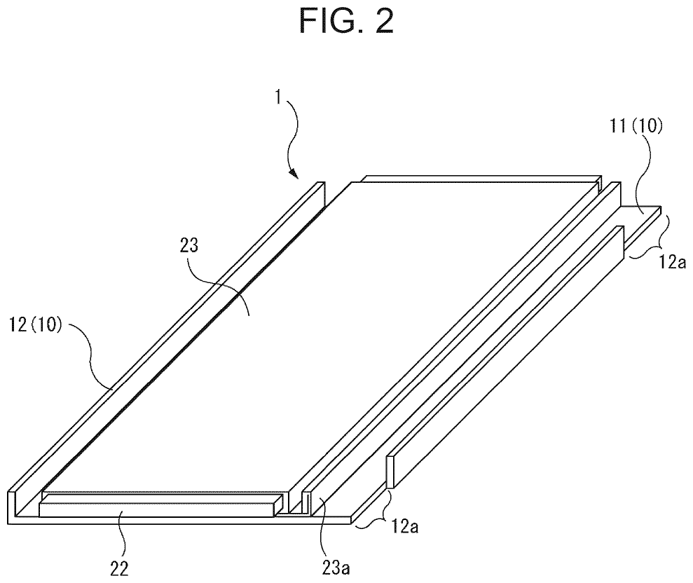

The disclosers and the like of the subject application have found that the above-mentioned insulation inspection becomes difficult when, with respect to a cooling plate having both end portions being bent, that is, a cooling plate including a flat surface portion and a pair of side surface portions facing each other, a battery is disposed on the above-mentioned flat surface portion and between the above-mentioned pair of side surface portions to configure a battery assembly as exemplified in FIG. 2.

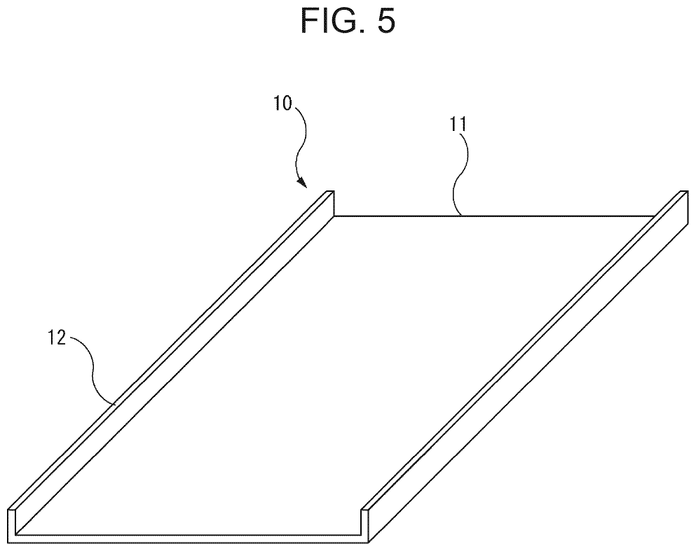

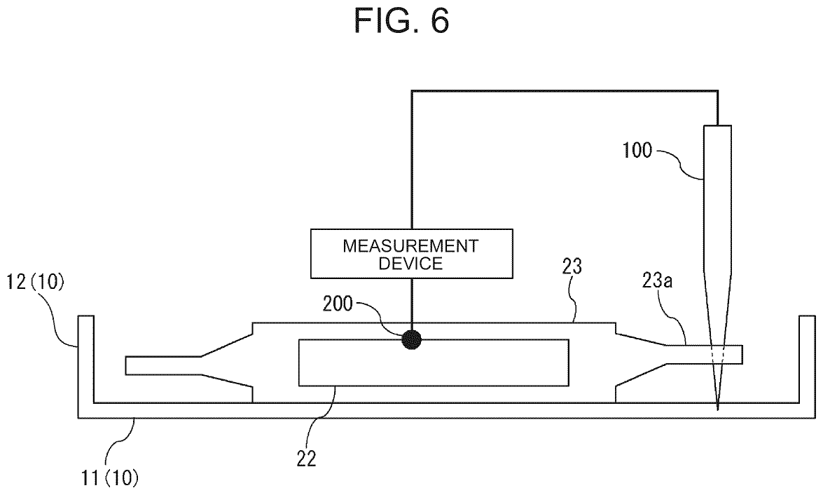

Specifically, for example, in a battery assembly including a cooling plate having no cutout or through-hole in a side surface portion thereof as exemplified in FIG. 5, when an inspection terminal is caused to pierce an extending portion of a laminating film to bring the inspection terminal into contact with a metal layer as exemplified in FIG. 6, the inspection terminal and the cooling plate come into contact with each other, and thus an appropriate insulation inspection may not be allowed. Further, it is conceivable to dispose a receiving member between the extending portion of the laminating film and the cooling plate in such a battery assembly to avoid contact between the inspection terminal and the cooling plate, but disposing such a receiving member is difficult in terms of structure.

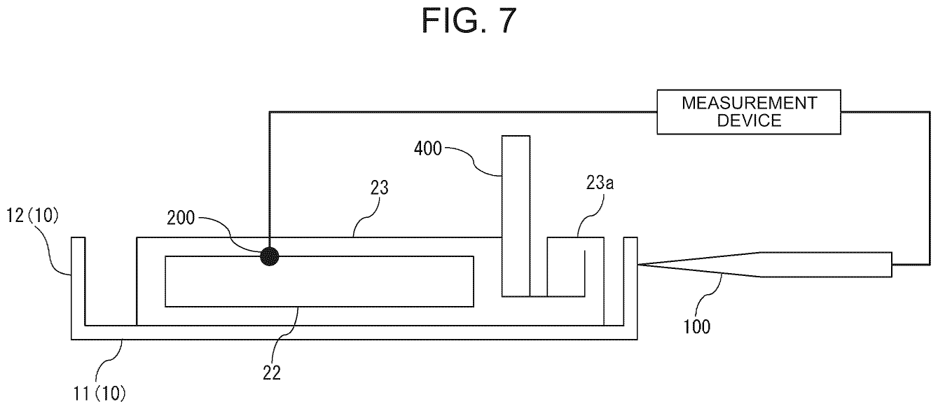

Further, it is conceivable to, for example, bend the extending portion of the laminating film toward an electrode stack, and pierce the extending portion of the laminating film with an inspection terminal from a side of the side surface portion of the battery to bring the inspection terminal into contact with the metal layer. However, as exemplified in FIG. 7, even when this method is attempted to be carried out, the side surface portion of the cooling plate becomes an obstacle, and thus the inspection terminal cannot reach the laminating film.

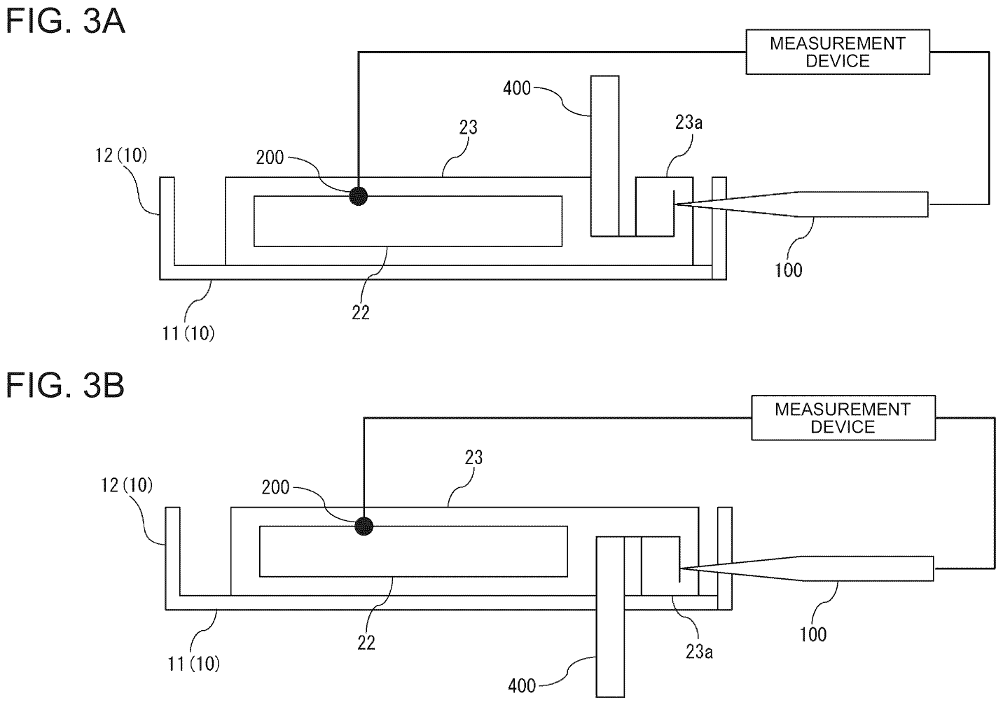

The disclosers and the like of the subject application have found that, as exemplified in FIGS. 1 and 2, when the cutout or through-hole 12a is provided in the side surface portion 12 of the cooling plate 10, an insulation inspection of a battery assembly 1 including such a cooling plate 10 can be appropriately performed. That is, the disclosers and the like of the subject application have found that, as exemplified in FIG. 3A and FIG. 3B, an inspection terminal can be caused to piece an extending portion 23a of a laminating film 23 through the above-mentioned cutout or through-hole 12a to bring the inspection terminal into contact with the metal layer.

Note that FIGS. 1 and 2 exemplify an aspect in which the side surface portion of the cooling plate has a cutout. Further, FIG. 3A, FIG. 3B, and FIGS. 6 and 7 are schematic side views of the battery assembly as viewed from the side of the current collector terminal.

As exemplified in FIG. 1, the cooling plate 10 for battery of the present disclosure includes the flat surface portion 11, and the pair of side surface portions 12 facing each other. As exemplified in FIG. 2, the battery assembly 1 can be formed by disposing a battery 20 on the flat surface portion 11 of the cooling plate 10. Further, a battery module can be formed by housing a plurality of battery assemblies 1 in a case. At this time, the pair of side surface portions 12 of the cooling plate 10 can be brought into contact with the case or another component housed in the case. In this manner, heat generated in charging and discharging of the battery 20 is dissipated to another member through the cooling plate 10, and thus the battery 20 is cooled.

In the cooling plate 10 for battery of the present disclosure, the side surface portion 12 has the cutout or through-hole 12a. With such a configuration, it is possible to prevent the side surface portion 12 of the cooling plate 10 from becoming an obstacle of the insulation inspection when the insulation inspection is carried out with respect to the battery assembly 1 including the cooling plate 10 for battery of the present disclosure.

As described above, the side surface portion of the cooling plate has a function of conducting heat generated in the charging and discharging of the battery to another member. The shape, the size, and the like of the cutout or through-hole are not particularly limited, and can be designed as appropriate in consideration of easiness of passage of the inspection terminal at the time of performing the insulation inspection of the battery assembly, a required heat conduction area, and the like.

Note that FIG. 1 exemplifies an aspect in which the cutout or through-hole 12a is provided in both end portions of the side surface portion 12 of the cooling plate 10, but the cutout or through-hole 12a is only required to be present at least at one portion.

In the cooling plate 10 for battery of the present disclosure, the cutout or through-hole 12a may be provided in at least one end portion of the side surface portion 12. A solid-state battery, particularly an all-solid-state battery has a strict moisture permeation standard. With the above-mentioned configuration, a hole formed by piercing the extending portion 23a of the laminating film 23 with the inspection terminal through the cutout or through-hole 12a can be kept away from an electrode part of the battery 20, and thus the influence of moisture with respect to the electrode part can be decreased.

Note that, in the present disclosure, the term “solid-state battery” means a battery using at least a solid electrolyte as an electrolyte. Thus, the solid-state battery may use a combination of a solid electrolyte and a liquid electrolyte as the electrolyte. Further, the solid-state battery of the present disclosure may be an all-solid-state battery, that is, a battery using only a solid electrolyte as the electrolyte.

As exemplified in FIG. 1, in the cooling plate 10 for battery of the present disclosure, the cutout or through-hole 12a may be provided in both end portions of the side surface portion 12. With such a configuration, in an inspection method for the battery assembly to be described later, when two inspection terminals are caused to pierce the extending portion 23a of the laminating film 23 to bring the two inspection terminals into contact with the metal layer and continuity between the two inspection terminals is checked, two holes formed in the extending portion 23a of the laminating film 23 can both be kept away from the electrode part of the battery 20, and thus the influence of moisture with respect to the electrode part can be decreased.

In the present disclosure, the term “end portion” of the side surface portion of the cooling plate for battery means a region in which a distance from a terminal end of the side surface portion in a long-side direction thereof falls within a predetermined range. The predetermined range can be determined in consideration of the shape, the size, and the like of the electrode part in the battery.

In the cooling plate for battery of the present disclosure, at least a part of the flat surface portion and the side surface portion may be a high thermal conductive material. In particular, the entire cooling plate may be a high thermal conductive material. The high thermal conductive material may be a metal such as stainless steel, silver, copper, gold, aluminum, nickel, or platinum, and may particularly be aluminum.

On the flat surface portion, a battery configuring the battery assembly to be described later is disposed. The shape, the size, and the like of the flat surface portion are not particularly limited, and can be designed as appropriate in consideration of the shape, the size, and the like of the battery.

The side surface portion has, in addition to the function of conducting heat from the battery to another member, a function of protecting the battery and a function as a guide for disposing another member. The shape, the size, and the like of a part other than the part of the side surface portion in which the cutout or through-hole is provided are not particularly limited, and can be designed as appropriate in consideration of each of the above-mentioned functions of the side surface portion.

### Battery Assembly

As exemplified in FIG. 2, the battery assembly 1 of the present disclosure includes the cooling plate 10 for battery of the present disclosure, and the battery 20 disposed on the flat surface portion 11 of the cooling plate 10 for battery. The battery 20 in the battery assembly 1 of the present disclosure includes an electrode stack 21, a current collector terminal 22 electrically connected to a current collector portion of the electrode stack 21, and a laminating film 23 that seals the electrode stack 21. The laminating film 23 includes a fusion resin layer, a metal layer, and a protection resin layer, and also an extending portion 23a extending at a peripheral edge of the electrode stack 21. The extending portion 23a is bent toward the electrode stack 21, and the cooling plate 10 for battery is disposed such that the side surface portion 12 of the cooling plate 10 for battery faces the bent extending portion 23a.

As described above, the disclosers and the like of the subject application have found that, at the time of performing the insulation inspection for such a battery assembly 1, the inspection terminal can be caused to pierce the extending portion 23a of the laminating film 23 through the cutout or through-hole 12a to bring the inspection terminal into contact with the metal layer.

The battery assembly 1 of the present disclosure includes the cooling plate 10 for battery of the present disclosure, and the battery 20 disposed on the flat surface portion 11 of the cooling plate 10 for battery.

### Cooling Plate for Battery

As for the cooling plate 10 for battery of the present disclosure, the description above regarding the cooling plate 10 for battery of the present disclosure can be referred to.

### Battery

The battery 20 includes the electrode stack 21, the current collector terminal 22 electrically connected to the current collector portion of the electrode stack 21, and the laminating film 23 that seals the electrode stack 21.

The laminating film 23 includes the fusion resin layer, the metal layer, and the protection resin layer, and also the extending portion 23a extending at the peripheral edge of the electrode stack 21. In this case, the metal layer is disposed for the purpose of blocking moisture or the like. When the laminating film includes the metal layer, a short-circuit may be caused between the metal layer and the current collector terminal and between the metal layer and the cooling plate. Thus, the disclosers and the like of the subject application have proposed inspecting the presence or absence of those short-circuits by an inspection method for a battery assembly to be described later.

The extending portion 23a is bent toward the electrode stack 21, and the cooling plate 10 for battery is disposed such that the side surface portion 12 of the cooling plate 10 for battery faces the bent extending portion 23a. With such a configuration, in the inspection method for the battery assembly to be described later, the inspection can be performed while the inspection terminal and the cooling plate are prevented from coming into contact with each other. Note that the extending portion may be formed by a fusion end portion obtained by fusing fusion resin layers of end portions of the laminating film.

Hereinafter, elements configuring the battery of the present disclosure are described.

### Electrode Stack

The electrode stack 21 functions as a power generation element of the battery. The shape of the electrode stack is not particularly limited, but may include, for example, a top surface portion, a bottom surface portion facing the top surface portion, and four side surface portions each coupling the top surface portion and the bottom surface portion to each other. The shape of the top surface portion is not particularly limited, but examples thereof include quadrangles such as a square, a rectangle, a rhombus, a trapezoid, and a parallelogram. Further, the shape of the top surface portion may be a polygon other than a quadrangle, or may be a shape having a curve such as a circle. Further, the same holds true for the shape of the bottom surface portion as the shape of the top surface portion. The shape of the side surface portion is not particularly limited, but examples thereof include quadrangles such as a square, a rectangle, a rhombus, a trapezoid, and a parallelogram.

The electrode stack may include a negative electrode current collector, a negative electrode active material layer, an electrolyte layer, a positive electrode active material layer, and a positive electrode current collector in the stated order.

### Current Collector Terminal

The current collector terminal 22 is electrically connected to the current collector portion of the electrode stack 21. The material of the current collector terminal is not particularly limited as long as the material has a current collecting function. Copper, aluminum, or the like is exemplified. The current collector terminal may be disposed in a pair of facing side surface portions of the electrode stack. The shape, the size, and the like of the current collector terminal are not particularly limited. The current collector terminal may seal the electrode stack together with the laminating film.

### Laminating Film

The laminating film 23 seals the electrode stack 21. The laminating film 23 may seal the electrode stack 21 together with the current collector terminal 22. Specifically, the laminating film may seal the electrode stack together with the current collector terminal by being wound around the electrode stack and the current collector terminal. Further, the laminating film may be configured of first and second films. In this case, the first and second films may sandwich the electrode stack and the current collector terminal from top and bottom in a stacking direction of the electrode stack to seal the electrode stack together with the current collector terminal.

The laminating film may include the fusion resin layer, the metal layer, and the protection resin layer in the stated order along the thickness direction thereof. Examples of the material of the fusion resin layer include olefin-based resins such as polypropylene (PP) and polyethylene (PE). Examples of the material of the metal layer include aluminum, an aluminum alloy, and stainless steel. Examples of the material of the protection resin layer include polyethylene terephthalate (PET) and nylon.

The battery may be a lithium-ion secondary battery. Examples of the application of the battery include a power supply for a vehicle such as a hybrid electric vehicle (HEV), a plug-in hybrid electric vehicle (PHEV), a battery electric vehicle (BEV), a gasoline vehicle, or a diesel vehicle. In particular, the battery is preferably used for a power supply for drive for the hybrid electric vehicle (HEV), the plug-in hybrid electric vehicle (PHEV), or the battery electric vehicle (BEV). Further, the battery in the present disclosure may be used as a power supply for a mobile object other than a vehicle (for example, a train, a ship, or an airplane), or may be used as a power supply for an electric product such as an information processing device.

### Inspection Method for Battery Assembly

A method of inspecting the battery assembly of the present disclosure includes the following steps: (a) piercing the extending portion 23a of the laminating film 23 with a first inspection terminal 100 through the cutout or through-hole 12a of the cooling plate 10 for battery of the present disclosure to bring the first inspection terminal 100 into contact with the metal layer; (b) bringing a second inspection terminal 200 into contact with the current collector terminal 22, and evaluating continuity between the first inspection terminal 100 and the second inspection terminal 200 to evaluate presence or absence of a short-circuit between the metal layer and the current collector terminal 22; and (c) bringing a third inspection terminal 300 into contact with the cooling plate 10 for battery, and evaluating continuity between the first inspection terminal 100 and the third inspection terminal 300 to evaluate presence or absence of a short-circuit between the metal layer and the cooling plate 10 for battery.

As exemplified in FIG. 3A and FIG. 3B, the method of the present disclosure includes (a) piercing the extending portion 23a of the laminating film 23 with the first inspection terminal 100 through the cutout or through-hole 12a of the cooling plate 10 for battery of the present disclosure to bring the first inspection terminal 100 into contact with the metal layer. The method of the present disclosure may include inserting a receiving member 400 between the bent extending portion 23a and another part of the laminating film 23. With such a method, the first inspection terminal 100 may easily pierce the extending portion 23a. Further, for example, the first inspection terminal 100 is caused to pass through the extending portion 23a to pierce the receiving member. Thus, the first inspection terminal 100 is held by the receiving member, resulting in that the first inspection terminal 100 can be easily avoided from coming into contact with a component other than the component to be inspected.

Note that FIG. 3A illustrates an aspect in which the extending portion 23a of the laminating film 23 is bent to a side opposite to the cooling plate 10 for battery, and FIG. 3B illustrates an aspect in which the extending portion 23a of the laminating film 23 is bent to the side of the cooling plate 10 for battery. For example, the cutout 12a provided in the side surface portion 12 of the cooling plate 10 for battery is extended up to a part of the flat surface portion 11 of the cooling plate 10 for battery. Thus, as the aspect illustrated in FIG. 3B, the receiving member 400 can be inserted and the step (a) can be carried out.

The first inspection terminal 100 is not particularly limited, and may be, for example, a probe. In particular, the first inspection terminal 100 may be a needle-shaped probe that can pierce the extending portion 23a of the laminating film 23.

The method of the present disclosure includes (b) bringing the second inspection terminal 200 into contact with the current collector terminal 22, and evaluating continuity between the first inspection terminal 100 and the second inspection terminal 200 to evaluate presence or absence of a short-circuit between the metal layer and the current collector terminal 22. This evaluation can use the first inspection terminal 100 and the second inspection terminal 200, and a device that is connected to each of those inspection terminals and can evaluate electrical characteristics. Specifically, for example, there is given a method including measuring an insulation resistance between the metal layer and the current collector terminal 22 when a predetermined voltage is applied to the first inspection terminal 100 and the second inspection terminal 200, and determining that a short-circuit is caused between the metal layer and the current collector terminal 22 when the insulation resistance is smaller than a reference value determined in advance. In addition, there is given a method including measuring a withstand voltage between the metal layer and the current collector terminal 22 when a predetermined voltage is applied to the first inspection terminal 100 and the second inspection terminal 200, and determining that a short-circuit is caused between the metal layer and the current collector terminal 22 when a dielectric breakdown occurs.

Note that the presence or absence of the short-circuit between the metal layer and the current collector terminal 22 can be evaluated between the metal layer and any one of the positive electrode current collector terminal 22 and the negative electrode current collector terminal 22.

The second inspection terminal 200 is not particularly limited, and may be, for example, a probe.

The method of the present disclosure includes (c) bringing the third inspection terminal 300 into contact with the cooling plate 10 for battery, and evaluating continuity between the first inspection terminal 100 and the third inspection terminal 300 to evaluate presence or absence of a short-circuit between the metal layer and the cooling plate 10 for battery. This evaluation can be performed in a similar way as the step (b).

The third inspection terminal 300 is not particularly limited, and may be, for example, a probe.

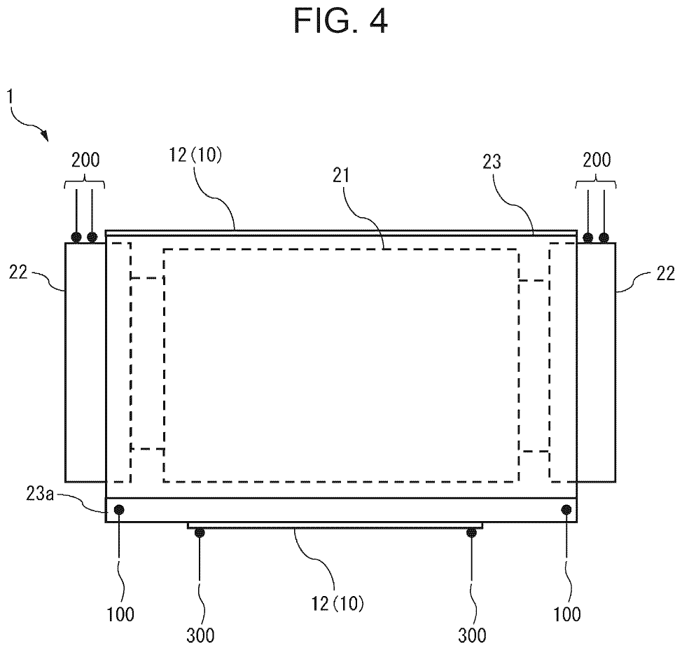

As exemplified in FIG. 4, the method of the present disclosure may include the following steps before the step (a): piercing the extending portion 23a of the laminating film 23 with two first inspection terminals 100 at positions different from each other to bring the two first inspection terminals 100 into contact with the metal layer, and checking continuity between the two first inspection terminals 100; bringing two second inspection terminals 200 into contact with the current collector terminal 22 at positions different from each other, and checking continuity between the two second inspection terminals 200; and bringing two third inspection terminals 300 into contact with the cooling plate 10 for battery at positions different from each other, and checking continuity between the two third inspection terminals 300. Note that FIG. 4 is a schematic plan view illustrating an aspect in which the two first inspection terminals, the two second inspection terminals, and the two third inspection terminals are brought into contact with the battery assembly exemplified in FIG. 2.

For example, when the first to third inspection terminals are not in contact with the member to be inspected, presence or absence of the short-circuit between the members cannot be appropriately evaluated. With this regard, when the method as described above is included, it is possible to check in advance that each inspection terminal is brought into contact with the member to be inspected.

As the method of checking the continuity between the first inspection terminals to the third inspection terminals, there is exemplified a method of using a device that is connected to each inspection terminal and can evaluate the electric characteristics. Specifically, for example, there is given a method including measuring an insulation resistance between the metal layers of the laminating film 23 when a predetermined voltage is applied between the first inspection terminals 100, and determining that the continuity is achieved between the metal layers when the insulation resistance is smaller than a reference value determined in advance. A similar method can also be adopted as the method of checking the continuity between the second and third inspection terminals 200, 300. Note that, when the continuity between the second inspection terminals 200 is checked, the two second inspection terminals can be respectively brought into contact with the positive electrode current collector terminal and the negative electrode current collector terminal.

### Battery Assembly After Inspection

The battery assembly after inspection is the battery assembly 1 after being subjected to inspection by the inspection method for the battery assembly of the present disclosure, and has a hole formed by piercing the extending portion 23a of the laminating film 23 of the battery 20 with the first inspection terminal 100. As for the inspection method for the battery assembly of the present disclosure, the description above relating to the inspection method for the battery assembly of the present disclosure can be referred to.

### Battery Module

The battery module includes the battery assembly 1 of the present disclosure, and a case that houses the battery assembly 1. The battery module may be configured of the battery assembly of the present disclosure after being subjected to inspection by the inspection method for the battery assembly of the present disclosure. The number of battery assemblies of the present disclosure in the battery module is not particularly limited. In the battery module, at least one battery assembly may be the battery assembly of the present disclosure. In particular, in the battery module, all of the battery assemblies may be the battery assembly of the present disclosure. As for the battery assembly of the present disclosure, the description above relating to the battery assembly of the present disclosure can be referred to. As for the inspection method for the battery assembly of the present disclosure, the description above relating to the inspection method for the battery assembly of the present disclosure can be referred to.

What is claimed is:

1. A cooling plate for battery comprising:
a flat surface portion; and
a pair of side surface portions facing each other, wherein a cutout or through-hole is formed in at least one of the side surface portions.

2. The cooling plate for battery according to claim 1, wherein the cutout or through-hole is provided in at least one end portion of the side surface portions.

3. A battery assembly comprising:
the cooling plate for battery of claim 1; and
a battery disposed on the flat surface portion of the cooling plate for battery,
wherein:
the battery includes an electrode stack, a current collector terminal electrically connected to a current collector portion of the electrode stack, and a laminating film that seals the electrode stack;
the laminating film includes a fusion resin layer, a metal layer, and a protection resin layer, and also an extending portion extending at a peripheral edge of the electrode stack;
the extending portion is bent toward the electrode stack; and
the cooling plate for battery is disposed such that at least one of the side surface portions of the cooling plate for battery faces the bent extending portion.

4. An inspection method for the battery assembly of claim 3, the inspection method comprising the following steps of:
(a) piercing the extending portion of the laminating film with a first inspection terminal through the cutout or through-hole of the cooling plate for battery to bring the first inspection terminal into contact with the metal layer;
(b) bringing a second inspection terminal into contact with the current collector terminal, and evaluating continuity between the first inspection terminal and the second inspection terminal to evaluate presence or absence of a short-circuit between the metal layer and the current collector terminal; and
(c) bringing a third inspection terminal into contact with the cooling plate for battery, and evaluating continuity between the first inspection terminal and the third inspection terminal to evaluate presence or absence of a short-circuit between the metal layer and the cooling plate for battery.

5. The inspection method according to claim 4, further comprising the following steps before the step (a):
piercing the extending portion of the laminating film with two first inspection terminals at positions different from each other to bring the two first inspection terminals into contact with the metal layer, and checking continuity between the two first inspection terminals;
bringing two second inspection terminals into contact with the current collector terminal at positions different from each other, and checking continuity between the two second inspection terminals; and
bringing two third inspection terminals into contact with the cooling plate for battery at positions different from each other, and checking continuity between the two third inspection terminals.
